(19) United States
(12) Patent Application Publication
(10) Pub. No.: US 2012/0257467 A1
(43) Pub. Date: Oct. 11, 2012

(54) MEMORY REPAIR ANALYSIS APPARATUS, MEMORY REPAIR ANALYSIS METHOD, AND TEST APPARATUS

(75) Inventors: Masaaki Kosugi, Gunma (JP); Seiji KOIKE, Saitama (JP)

(73) Assignee: ADVANTEST CORPORATION, Tokyo (JP)

(21) Appl. No.: 13/411,643

(22) Filed: Mar. 5, 2012

(30) Foreign Application Priority Data
Apr. 6, 2011 (JP) 2011-084220

(51) Int. Cl. G11C 29/44

(52) U.S. Cl. 365/200

(57) ABSTRACT

A memory repair analysis apparatus that performs a repair analysis on a memory under test, comprising a row-oriented fail number storage section that stores the number of fail cells in each row; a column-oriented fail number storage section that stores the number of fail cells in each column; a row-weighting storage section that, for each row, stores the total number of fail cells in each column containing a fail cell included in the row; a column-weighting storage section that, for each column, stores the total number of fail cells in each row containing a fail cell included in the column; and a determining section that determines which of spare row regions and spare column regions are to replace the fail cells.

### BACKGROUND

1. Technical Field

The present invention relates to a memory repair analysis apparatus, a memory repair analysis method, and a test apparatus.

2. Related Art

A conventional memory device is known that includes redundant memory cells. When a defect is discovered in a portion of the memory cells during testing after manufacturing of such a memory device, a repair process is performed to replace the defective cells with redundant memory cells, thereby creating a functional device. In other words, after the repair process, when an address is designated in the memory device to access a defective cell, a redundant memory cell is accessed instead of the defective cell. Conventionally, a test apparatus performs a repair analysis after the memory under test has been tested, and determines how to allocate the redundant cells to the plurality of defective cells based on defect information in the test results, as described in Patent Document 1, for example.

Patent Document 1: Japanese Patent Application Publication No. H11-213695

The memory repair analysis includes a one-dimensional repair analysis (line fail analysis) performed by hardware executing a relatively simple process, and a two-dimensional repair analysis (bit fail analysis) performed by software executing a relatively complicated process. Therefore, it is necessary to use a high-speed and expensive CPU to execute the software, in addition to the hardware performing the one-dimensional repair analysis.

### SUMMARY

Therefore, it is an object of an aspect of the innovations herein to provide a memory repair analysis apparatus, a memory repair analysis method, and a test apparatus, which are capable of overcoming the above drawbacks accompanying the related art. The above and other objects can be achieved by combinations described in the independent claims. The dependent claims define further advantageous and exemplary combinations of the innovations herein. According to a first aspect related to the innovations herein, provided is a memory repair analysis apparatus that performs a repair analysis on a memory under test including spare row regions for repairing memory regions in a row direction and spare column regions for repairing memory regions in a column direction. The memory repair analysis apparatus comprises a row-oriented fail number storage section that stores the number of fail cells in each row; a column-oriented fail number storage section that stores the number of fail cells in each column; a row-weighting storage section that, for each row, stores the total number of fail cells in each column containing a fail cell included in the row; a column-weighting storage section that, for each column, stores the total number of fail cells in each row containing a fail cell included in the column; and a determining section that determines which of the spare row regions and the spare column regions are to replace the fail cells, based on the values stored in the row-oriented fail number storage section, the column-oriented fail number storage section, the row-weighting storage section, and the column-weighting storage section.

The summary clause does not necessarily describe all necessary features of the embodiments of the present invention. The present invention may also be a sub-combination of the features described above.

### BRIEF DESCRIPTION OF THE DRAWINGS

FIG. 1 shows an exemplary configuration of a test apparatus 100 according to an embodiment of the present invention, along with a memory under test 10.

FIG. 2 shows an exemplary configuration of the analyzing section 130 according to the present embodiment.

FIG. 3 shows an exemplary operational flow of the test apparatus 100 according to the present embodiment.

FIG. 4A shows an exemplary initial state of the repair analysis performed by the analyzing section 130 of the present embodiment on a partial memory region of the memory under test 10.

FIG. 4B shows an example in which the analyzing section 130 of the present embodiment has determined two repair target columns.

FIG. 4C shows an example in which the analyzing section 130 of the present embodiment has set two repair target rows.

FIG. 5 shows an exemplary modification of the operational flow of the test apparatus 100 according to the present embodiment.

FIG. 6 shows a modification of the analyzing section 130 according to the present embodiment.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

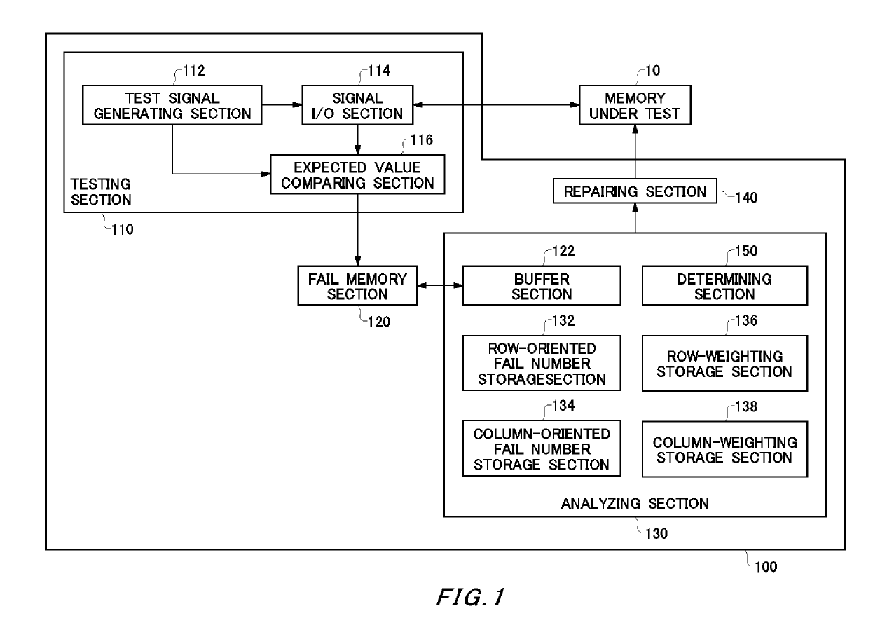

FIG. 1 shows an exemplary configuration of a test apparatus 100 according to an embodiment of the present invention, along with a memory under test 10. The test apparatus 100 detects fail cells by testing the memory under test 10, which includes spare row regions for repairing memory regions in a row direction and spare column regions for repairing memory regions in a column direction, and acquires position information for the fail cells. Here, the memory under test 10 is a memory device that includes a memory matrix of memory cells arranged physically or logically in row and column directions.

When the memory under test 10 is accessed at an address of a column or row that includes a fail cell by a repair process after testing, rows and columns of non-defective memory regions within redundant circuitry are accessed so that the memory under test 10 operates as a non-defective memory. The memory under test 10 includes, in the non-defective memory regions within the redundant circuitry, spare row regions that replace memory cells arranged in a row direction and spare column regions that replace memory cells in a column direction.

The memory under test 10 may include a plurality of memory blocks, and may independently include spare row regions and spare column regions for each of the memory blocks. The memory under test 10 may be a semiconductor memory such as a DRAM, SRAM, or flash memory, or may instead by a memory included in an LSI, such as a microprocessor.

The test apparatus 100 performs a repair analysis on the memory under test 10 based on the fail cell position information, to determine repair target rows and repair target columns. The test apparatus 100 performs a repair process of the memory under test 10 by replacing the repair target rows with spare row regions and replacing the repair target columns with spare column regions, based on the repair analysis results. The test apparatus 100 may perform testing and the repair analysis according to a test program. The test apparatus 100 includes a testing section 110, a fail memory section 120, an analyzing section 130, and a repairing section 140.

The testing section 110 exchanges electrical signals with the memory under test 10 including redundant circuitry, to test the memory under test 10. If the memory under test 10 includes a plurality of memory regions, the testing section 110 may perform a test for each memory region. The testing section 110 inputs to the memory under test 10 a test signal based on a test pattern for testing the memory under test 10, and judges pass/fail of the memory under test 10 based on an output signal that is output by the memory under test 10 in response to the test signal. The testing section 110 includes a test signal generating section 112, a signal input/output section 114, and an expected value comparing section 116.

The test signal generating section 112 is connected to one or more memories under test 10 via the signal input/output section 114, and generates a plurality of test signals to be supplied to the memory under test 10. The test signal generating section 112 may generate an expected value for the response signal output by the memory under test 10 in response to the test signal.

The signal input/output section 114 is connected to one or more memories under test 10, and exchanges electrical signals between the testing section 110 and the memory under test 10. The signal input/output section 114 may be a performance board on which a plurality of memories under test 10 are mounted. The signal input/output section 114 may include a plurality of switches provided in transmission paths connected respectively to the memories under test 10, and may switch between an electrical connection and a disconnection between the testing section 110 and each memory under test 10.

The signal input/output section 114 creates an electrical connection between the testing section 110 and the memory under test 10 to be tested, and transmits the test signal generated by the test signal generating section 112 to the memory under test 10. The signal input/output section 114 receives the output signal that is output by the memory under test 10 in response to the test signal. The signal input/output section 114 transmits the received output signal of the memory under test 10 to the expected value comparing section 116.

The expected value comparing section 116 compares the data value included in the output signal of the memory under test 10 received from the signal input/output section 114 to the expected value generated by the test signal generating section 112. The expected value comparing section 116 judges pass/fail of the memory under test 10 based on the comparison result. The expected value comparing section 116 stores, in the fail memory section 120, address information of the detected fail cells and judgment results from the testing of the memory under test 10, for example.

The fail memory section 120 stores fail cell information for each memory region in the memory under test 10. If the memory under test 10 includes a plurality of memory regions, the fail memory section 120 may store the fail cell information for each memory region. Here, the memory under test 10 may include a plurality of memory regions that each include corresponding row repair regions and column repair regions.

When the testing section 110 sequentially tests the memory regions of the memory under test 10 one portion at a time, the fail memory section 120 should have a storage region that has at least enough capacity to store the fail cell information of the memory region portion tested during a single test. Furthermore, a plurality of fail memory sections 120 corresponding to the plurality of memories under test 10 may be provided in the test apparatus 100. Yet further, a plurality of fail memory sections 120 corresponding respectively to the plurality of memory regions of the memory under test 10 may be provided.

The analyzing section 130 performs the repair analysis of the memory under test 10 based on fail cell information stored in the fail memory section 120. A plurality of analyzing sections 130 may be provided in the test apparatus 100. For example, if there are a plurality of fail memory sections 120 in the test apparatus 100, an analyzing section 130 may be provided for each fail memory section 120. A plurality of analyzing sections 130 may be provided to correspond to the plurality of memories under test 10. The analyzing section 130 includes a buffer section 122, a row-oriented fail number storage section 132, a column-oriented fail number storage section 134, a row-weighting storage section 136, a column-weighting storage section 138, and a determining section 150.

The buffer section 122 reads fail information for a predetermined memory region of the memory under test 10 from the fail memory section 120, and stores this fail information. If the memory under test 10 includes a plurality of memory regions that each include corresponding row repair regions and column repair regions, the buffer section 122 may read the fail information for each memory region and store this fail information. The buffer section 122 may map the fail cell information in association with position information of the memory cells stored in the fail memory section 120.

The row-oriented fail number storage section 132 stores the number of fail cells in each row of the memory region of the memory under test 10 stored in the buffer section 122. The column-oriented fail number storage section 134 stores the number of fail cells in each column of the memory region.

For each row of the memory region of the memory under test 10 stored in the buffer section 122, the row-weighting storage section 136 stores the total number of fail cells in columns containing a fail cell included in the row. The row-weighting storage section 136 may store a value that represents the total number of fail cells. The values stored in the row-weighting storage section 136 may be referenced by the determining section 150 as weightings for the corresponding rows.

For each column in the memory region, the column-weighting storage section 138 stores the total number of fail cells in rows that contain a fail cell included in the column. The column-weighting storage section 138 may store a value that represents the total number of fail cells. The values stored in the column-weighting storage section 138 may be referenced by the determining section 150 as weightings for the corresponding columns.

The determining section 150 determines which of the spare row regions and spare column regions of the memory under test 10 are to replace the fail cells, based on the values stored in the row-oriented fail number storage section 132, the column-oriented fail number storage section 134, the row-weighting storage section 136, and the column-weighting storage section 138. The determining section 150 determines which of the spare row regions and spare column regions are to replace the fail cells while prioritizing rows and columns for which a larger number of fail cells are stored in the row-oriented fail number storage section 132 and the column-oriented fail number storage section 134.

Rows and columns for which the number stored in the row-oriented fail number storage section 132 or column-oriented fail number storage section 134 is greater than the number stored for other rows and columns are treated as rows and columns having a relatively high number of fail cells. Accordingly, a plurality of fail cells can be repaired by replacing one of these rows or columns. Therefore, in order to efficiently repair the fail cells, the determining section 150 places higher priority on repairing these rows and columns than on repairing other rows and columns.

However, there are cases in which the determining section 150 cannot efficiently determine the order of repair, such as when numbers stored in the row-oriented fail number storage section 132 or the column-oriented fail number storage section 134 are the same. In such a case, the determining section 150 further references the values stored in the row-weighting storage section 136 and the column-weighting storage section 138, to determine which of the spare row regions and spare column regions are to replace the fail cells.

Among a plurality of rows or columns for which the same number of fail cells are stored in the row-oriented fail number storage section 132 and the column-oriented fail number storage section 134, the determining section 150 determines which spare row regions and spare column regions are to replace the fail cells while prioritizing the rows or columns that have smaller total values stored in the row-weighting storage section 136 or the column-weighting storage section 138. There is a high probability that there are one or more other fail cells within a column that contains a fail cell included in a row for which a larger number is stored in the row-weighting storage section 136.

In other words, by repairing this column, there is a higher chance that a plurality of fail cells, including the original fail cell, can be repaired than if a different column were repaired, and this means that there is a higher chance of replacement when the determining section 150 prioritizes this column. Accordingly, the determining section 150 lowers the priority of the row containing the original fail cell, such that the repair of this row does not needlessly overlap with the repair of the original fail cell by this column. At the same time that the column repair is performed, the determining section 150 increases the priority of rows for which a smaller number is stored in the row-weighting storage section 136 that have a lower chance of the fail cells contained therein being repaired.

Similarly, there is a high probability that there are one or more other fail cells within a row that contains a fail cell included in a column for which a larger number is stored in the column-weighting storage section 138, and therefore there is a high probability that the determining section 150 will perform replacement while prioritizing this row. Accordingly, the determining section 150 lowers the priority of the column containing the original fail cell, such that the repair of this column does not needlessly overlap with the repair of the original fail cell by this row. At the same time that the row repair is performed, the determining section 150 increases the priority of columns for which a smaller number is stored in the column-weighting storage section 138 that have a lower chance of the fail cells contained therein being repaired.

In this way, even when the same numbers are stored in the row-oriented fail number storage section 132 and the column-oriented fail number storage section 134, the determining section 150 can determine the replacement priority.

The determining section 150 clears the fail cell information of the rows and columns that have been determined to be replaced by spare row regions or spare column regions, and updates the values stored in the row-oriented fail number storage section 132, the column-oriented fail number storage section 134, the row-weighting storage section 136, and the column-weighting storage section 138. In this way, after a row or column to be replaced has been determined, the determining section 150 clears the fail cell information, and may repeat the determination of a row or column to be replaced until there are no more fail cells to replace.

If there are a plurality of rows or columns for which the same number of fail cells is stored in the row-oriented fail number storage section 132 and the column-oriented fail number storage section 134 and the total value stored in the row-weighting storage section 136 or the column-weighting storage section 138 for these rows or columns is also the same, the determining section 150 compares the total number of rows that have already been determined to be replaced by row repair regions to the total number of columns that have already been determined to be replaced by column repair regions, and if the total number of columns is greater, prioritizes the repair target to be the plurality of rows that have the minimum weighting.

Instead, when there are a plurality of rows or columns for which the same number of fail cells is stored in the row-oriented fail number storage section 132 and the column-oriented fail number storage section 134 and the total value stored in the row-weighting storage section 136 or the column-weighting storage section 138 for these rows or columns is also the same, if the number of fail numbers greater than or equal to 1 stored in the column-oriented fail number storage section 134 is greater than the number of fail numbers greater than or equal to 1 stored in the row-oriented fail number storage section 132, the determining section 150 determines that the rows are to be replaced while prioritizing the spare column regions.

Furthermore, when there are a plurality of rows or columns for which the same number of fail cells is stored in the row-oriented fail number storage section 132 and the column-oriented fail number storage section 134 and the total value stored in the row-weighting storage section 136 or the column-weighting storage section 138 for these rows or columns is also the same, if the number of fail numbers greater than or equal to 1 stored in the row-oriented fail number storage section 132 is greater than the number of fail numbers greater than or equal to 1 stored in the column-oriented fail number storage section 134, the determining section 150 determines that the columns are to be replaced while prioritizing the spare column regions. As described further below, using the above methods, even when there are plurality of rows or columns for which the same total value is stored in the corresponding row-weighting storage section 136 or column-weighting storage section 138, the determining section 150 can determine the replacement priority order.

The repairing section 140 performs the repair by replacing the rows or columns that the determining section 150 has determined are to be replaced with spare row regions or spare column regions, in the determined order. The repairing section 140 replaces the rows or columns to be replaced with the spare row regions or spare column regions according to a method of switching to redundant circuitry in the memory under test 10.

For example, when using a logic circuit to perform the method of switching to redundant circuitry in the memory under test 10, the repairing section 140 overwrites a program causing the logic circuit to operate to switch to the redundant circuitry. Instead, when using a cutting circuit to perform thermal cutting with a laser beam or the like as the method of switching to redundant circuitry in the memory under test 10, the repairing section 140 may perform the thermal cutting by emitting the laser beam or the like onto the corresponding cutting circuit. Instead, when using a fuse circuit to perform fusion cutting by causing current to flow as the method of switching to redundant circuitry in the memory under test 10, the repairing section 140 may perform the fusion cutting by causing a current with a current value in a predetermined range to flow through the corresponding fuse circuit.

The test apparatus 100 according to the present embodiment performs testing of a memory under test 10, a memory repair analysis of the memory under test 10 based on the test results, and a repair process based on the memory repair analysis results. The test apparatus 100 may perform the memory repair analysis after testing of the memory under test 10 is finished, or instead may perform the memory repair analysis of a predetermined partial memory region after the test results for this memory region have been stored in the fail memory section. The test apparatus 100 may perform the repair process of the repairing section 140 together with the memory repair analysis of the analyzing section 130.

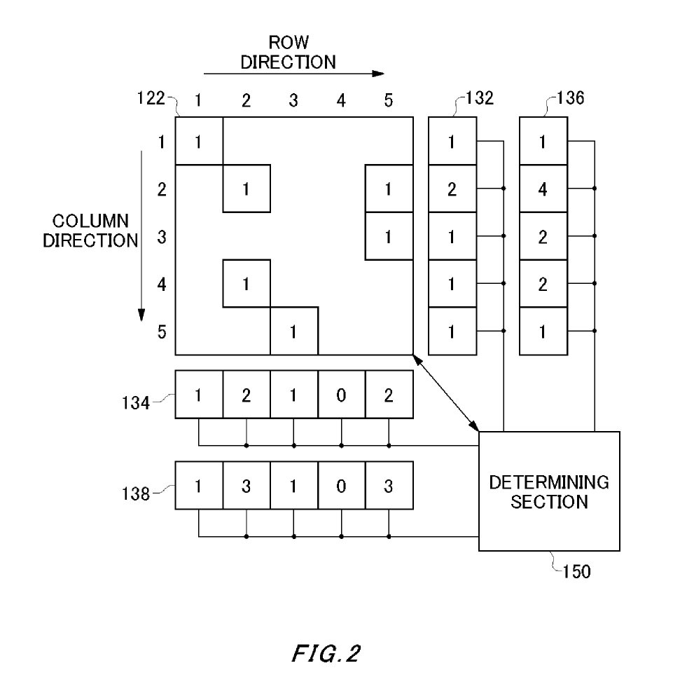

FIG. 2 shows an exemplary configuration of the analyzing section 130 according to the present embodiment. In the present embodiment, the memory under test 10 includes a 5 by 5 matrix of memory cells, two spare row regions for replacing row units of fail memory cells, and two spare column regions for replacing column units of fail memory cells. The buffer section 122 reads from the fail memory section 120 the fail information for the 5 by 5 memory region of the memory under test 10, and stores the fail information.

For example, the buffer section 122 may treat the horizontal direction in FIG. 2 as the row direction and treat the horizontal direction as the column direction. In other words, the row direction is the direction in which the column number is incremented by 1 at a time while keeping the same row number, and the column direction is the direction in which the row number is incremented by 1 at a time while keeping the same column number. In FIG. 2, the buffer section 122 uses “1” to represent a fail cell in a memory region.

The memory region of the buffer section 122 includes five rows, and therefore the row-oriented fail number storage section 132 and the row-weighting storage section 136 may each include at least five storage regions. Similarly, the memory region of the buffer section 122 includes five columns, and therefore the column-oriented fail number storage section 134 and the column-weighting storage section 138 may each include at least five storage regions.

Since the memory cell in the first row and first column is a fail cell, for example, the row-oriented fail number storage section 132 stores a value of 1 as the number of fails in the first row in the first storage region. Furthermore, the row-oriented fail number storage section 132 stores a value of 2 as the number of fails in the second row in the second storage region, and stores a value of 1 as the number of fails in each of the third to fifth rows respectively in the third to fifth storage regions. Similarly, the column-oriented fail number storage section 134 stores a value of 1 as the number of fails in each of the first and third columns, stores a value of 2 as the number of fails in each of the second and fifth columns, and stores a value of 0 as the number of fails in the fourth column.

A fail cell is located in the first column and the first row and the total number of fail cells in the first column is 1, and therefore the row-weighting storage section 136 stores a value of 1 in the first storage region. Fail cells are located at the second column and the fifth column in the second row and a total of 4 results from the 2 fail cells in the second column and the 2 fail cells in the fifth column, and therefore the row-weighting storage section 136 stores a value of 4 in the second storage region. In the same manner, the row-weighting storage section 136 stores a value of 2 in the third storage region, a value of 2 in the fourth storage region, and a value of 1 in the fifth storage region.

A fail cell is located in the first column and the first row and the total number of fail cells in the first row is 1, and therefore the column-weighting storage section 138 stores a value of 1 in the first storage region. Fail cells are located at the second row and the fourth row in the second column and a total of 3 results from the 2 fail cells in the second row and the 1 fail cell in the fourth row, and therefore the column-weighting storage section 138 stores a value of 3 in the second storage region. In the same manner, the column-weighting storage section 138 stores a value of 1 in the third storage region, a value of 0 in the fourth storage region, and a value of 3 in the fifth storage region.

The determining section 150 references the values stored in the row-weighting storage section 136 and the column-weighting storage section 138 to determine which of the spare row regions and spare column regions are to replace the fail cells. Furthermore, after determining which of the spare row regions and spare column regions are to replace the fail cells, the determining section 150 may clear the display of these fail cells in the buffer section 122.

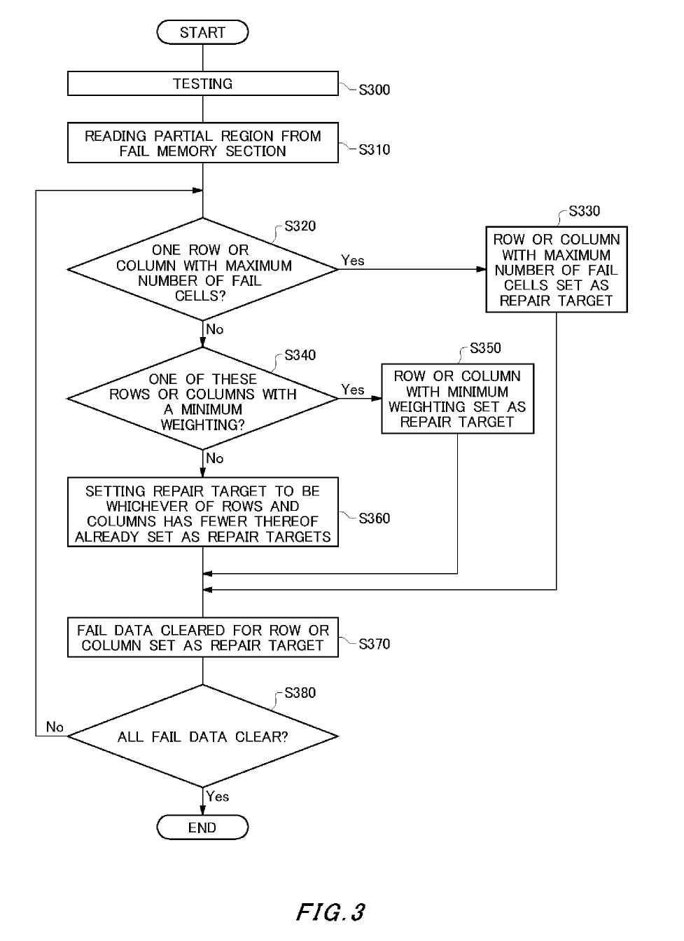

FIG. 3 shows an exemplary operational flow of the test apparatus 100 according to the present embodiment. The following describes an example in which the test apparatus 100 performs the memory repair analysis after finishing testing of the memory under test 10. The testing section 110 tests the memory under test 10 (S300). The testing section 110 stores the test results in the fail memory section 120.

Next, the buffer section 122 reads the information of the test results for a partial region of the memory under test 10 stored in the fail memory section 120, and stores this information (S310). As described in FIG. 2, the row-oriented fail number storage section 132 stores the number of fail cells for each row of the memory region stored in the buffer section 122, and the column-oriented fail number storage section 134 stores the number of fail cells for each column in the memory region.

Furthermore, as described in FIG. 2, for each row of the memory region stored in the buffer section 122, the row-weighting storage section 136 stores the total number of fail cells in columns containing a fail cell included within the row. Similarly, for each column of the memory region, the column-weighting storage section 138 stores the total number of fail cells in rows containing a fail cell included within the column.

Here, after the row-oriented fail number storage section 132 and the column-oriented fail number storage section 134 have stored the number of fail cells for each row and each column, the row-weighting storage section 136 and the column-weighting storage section 138 may each operate based on the number of stored fail cells. The following describes an example in which the buffer section 122 reads the information stored in the fail memory section 120 for each memory cell and stores the information.

Each time the buffer section 122 maps one piece of fail cell information, the row-oriented fail number storage section 132 and the column-oriented fail number storage section 134 may increment the fail cell number of the corresponding row and column by 1. In this case, the row-weighting storage section 136 and the column-weighting storage section 138 update the total number of fail cells based on the values in the row-oriented fail number storage section 132 and the column-oriented fail number storage section 134.

For example, when the buffer section 122 maps fail cell information at a position in the second row and the second column, the row-oriented fail number storage section 132 increments the value stored in the second storage region by 1 and the column-oriented fail number storage section 134 increments the value stored in the second storage region by 1. Next, the row-weighting storage section 136 updates the second total number of fail cells stored as the weighting of the second row. Similarly, the column-weighting storage section 138 updates the second fail cell total stored as the weighting of the second column.

Furthermore, when the buffer section 122 stores at a position in the second row and the fifth column, the row-oriented fail number storage section 132 increments the value stored in the second storage region by 1 and the column-oriented fail number storage section 134 increments the value stored in the fifth storage region by 1. Next, the row-weighting storage section 136 updates the second fail cell total stored as the weighting of the second row. Similarly, the column-weighting storage section 138 updates the fifth fail cell total stored as the weighting of the fifth column.

In this way, for each mapping of fail cell information of the buffer section 122, the row-oriented fail number storage section 132, the column-oriented fail number storage section 134, the row-weighting storage section 136, and the column-weighting storage section 138 may each update the values stored therein. Therefore, the buffer section 122 may perform mapping of one piece of fail information every other clock, for example. In this case, the row-oriented fail number storage section 132 and the column-oriented fail number storage section 134 may perform updates with the same clock at 1-clock intervals, and the row-weighting storage section 136 and the column-weighting storage section 138 may perform updates at 1-clock intervals with a clock differing from the clock used for the updates of the row-oriented fail number storage section 132 and the column-oriented fail number storage section 134.

Instead, the buffer section 122 can map one fail cell for each clock. In this case, the row-oriented fail number storage section 132, the column-oriented fail number storage section 134, the row-weighting storage section 136, and the column-weighting storage section 138 may perform updates with the same clock as the mapping clock. Instead, the row-oriented fail number storage section 132, the column-oriented fail number storage section 134, the row-weighting storage section 136, and the column-weighting storage section 138 may be updated after mapping of the buffer section 122 is finished. In this case, the buffer section 122 need not map the pieces of fail cell information 1 at a time.

Next, the determining section 150 references the number of fail cells stored in the row-oriented fail number storage section 132 and the column-oriented fail number storage section 134, and determines if there is one row or column that has the maximum number of fail cells (S320). If there is one row or column that has a maximum number of fail cells, the determining section 150 prioritizes this row or column to be set as the repair target (S330).

If there are two or more rows or columns that have the maximum number of fail cells, the determining section 150 references the values stored in the row-weighting storage section 136 or the column-weighting storage section 138, which indicate the weighting of the corresponding rows or columns. Here, the determining section 150 determines if there is one row or column that has a minimum weighting corresponding to the rows or columns having the maximum number of fail cells stored in the row-weighting storage section 136 and the column-weighting storage section 138 (S340). When there is one row or column with minimum weighting, the determining section 150 sets the repair target while prioritizes this row or column to be set as the repair target (S350).

When there are two or more rows or columns with minimum weightings, the determining section 150 compares the total number of rows that have already been set as repair targets to the total number of columns that have already been set as repair targets (S360). If the total number of columns that have been set as repair targets is greater, the determining section 150 prioritizes the plurality of rows that minimize this weighting to be the repair targets. If the total number of rows that have been set as repair targets is greater, the determining section 150 prioritizes the plurality of columns that minimize this weighting to be the repair targets. In this way, the determining section 150 can get closer to reaching an even balance between the number of rows and the number of columns set as repair targets.

Instead, the number of fail numbers greater than or equal to 1 stored in the row-oriented fail number storage section 132 may be compared to the number of fail numbers greater than or equal to 1 stored in the column-oriented fail number storage section 134. When this number is greater for the row-oriented fail number storage section 132, the determining section 150 may prioritize the columns as repair targets. When this number is greater for the column-oriented fail number storage section 134, the determining section 150 may prioritize the columns as repair targets. In other words, when the number of fail numbers greater than or equal to 1 stored in the row-oriented fail number storage section 132, this indicates that the fail cells are spread out across a plurality of rows, and therefore the determining section 150 selects the columns, which have fewer fail cells spread therein than the rows, to be the repair targets.

In the manner described above, the repairing section 140 replaces rows or columns set as repair targets by the determining section 150 with spare row regions or spare column regions of the memory under test 10. The repairing section 140 may make the replacement with the spare row regions or spare column regions each time the determining section 150 determines a repair target. Instead, after a predetermined number of repair targets have been determined, the repairing section 140 may sequentially replace the repair targets with the spare row regions or spare column regions in the order in which the determining section 150 determined the repair targets.

The determining section 150 clears the fail cell information in the buffer section 122 for the rows and columns that have been set as repair targets (S370). If there are fail cells remaining in the buffer section 122 that have yet to be cleared, the determining section 150 returns to step S320 and determines the next row or column to be prioritized for setting as the repair target (S380). The determining section 150 repeats the process from step S320 to step S380, until all of the fail cells are cleared from the buffer section 122. When all of the fail cells have been cleared from the buffer section 122, the determining section 150 ends the memory repair analysis.

With the operational flow of the present embodiment, the test apparatus 100 can test and perform a repair analysis of the memory under test 10. Furthermore, the test apparatus 100 of the present embodiment can perform the memory repair analysis using a relatively simple process that can be realized by hardware, and therefore there is no need to use an expensive CPU or the like for performing complex processing.

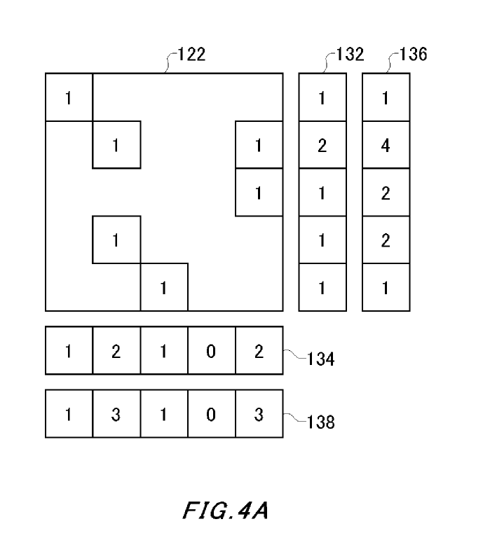

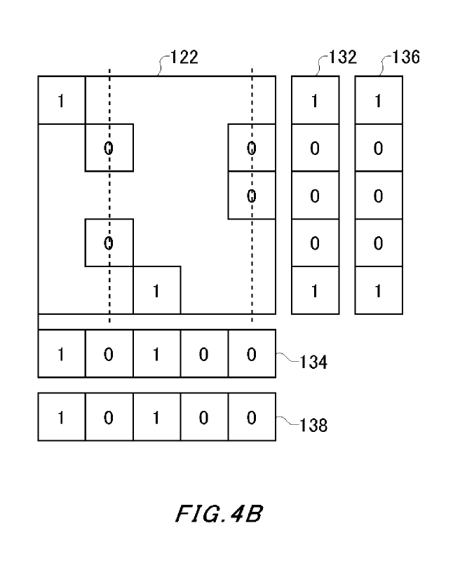

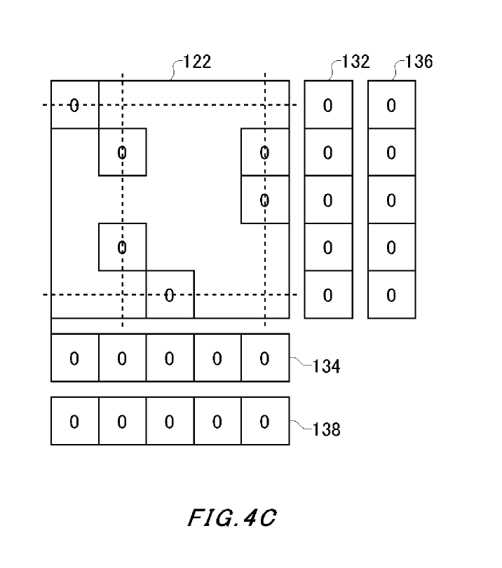

FIGS. 4A to 4C are used to describe how the values stored in the buffer section 122, the row-oriented fail number storage section 132, the column-oriented fail number storage section 134, the row-weighting storage section 136, and the column-weighting storage section 138 are changed through the memory repair analysis of the above operational flow. FIG. 4A shows an exemplary initial state of the repair analysis performed by the analyzing section 130 of the present embodiment on a partial memory region of the memory under test 10.

In the following example, as described in FIG. 2, the buffer section 122 reads from the fail memory section 120 the test results for a memory region that includes 25 memory cells, and stores the test results. The row-oriented fail number storage section 132, the column-oriented fail number storage section 134, the row-weighting storage section 136, and the column-weighting storage section 138 store the values shown in FIG. 2 as the initial values, and therefore a description of calculating the initial values is omitted.

The determining section 150 references the number of fail cells stored in the row-oriented fail number storage section 132 and the column-oriented fail number storage section 134, and determines that the rows or columns having the maximum number of fails cells are the second row, the second column, and the fifth column. Here, the maximum value for the number of fail cells is 2.

When the second column is prioritized as the repair target, for example, four fail cells remain respectively in the first row and first column, the third row and fifth column, the fourth row and second column, and the fifth row and third column. In this case, no matter which row or column is repaired next, it is impossible to simultaneously repair two or more of the four remaining fail cells. In other words, only one fail cell can be a repair target for one row or column, and the total number of rows or columns that are repair targets is therefore five, including the initial second row.

However, there are cases where the redundant circuitry of the memory under test 10 does not include a total of five spare row regions and spare column regions corresponding to this memory region, and in such a case the memory region cannot be repaired. In other words, even if the repair targets are determined according to the total number of fail cells in the row direction and column direction, there are cases in which an efficient repair analysis cannot be performed. Therefore, when there are two or more rows or columns containing the maximum number of fail cells, as in the present embodiment, the determining section 150 determines the row or column to be a repair target based on the values stored in the row-weighting storage section 136 or the column-weighting storage section 138 indicating the weighting of the corresponding rows or columns.

The determining section 150 determines whether there is one row or column that has the maximum number of fail cells and a minimum corresponding weighting stored in the row-weighting storage section 136 or the column-weighting storage section 138. The weighting of the second row is 4, the weighting of the second column is 3, and the weighting of the fifth column is 3, and therefore the determining section 150 determines that the second column and the fifth column are two rows or columns with the minimum weighting. The determining section 150 prioritizes these two columns as the repair targets.

FIG. 4B shows an example in which the analyzing section 130 of the present embodiment has determined two repair target columns. The determining section 150 clears the fail cell information of the second column and the fifth column set as repair targets in the buffer section 122. Specifically, the determining section 150 clears the fail cells at the second row and second column, the second row and fifth column, the third row and fifth column, and the fourth row and second column. In addition, the row-oriented fail number storage section 132, the column-oriented fail number storage section 134, the row-weighting storage section 136, and the column-weighting storage section 138 are updated to include information based on the remaining fail cells at the first row and first column and the fifth row and third column.

The determining section 150 again references the number of fail cells stored in the row-oriented fail number storage section 132 and the column-oriented fail number storage section 134, and determines that there are four rows or columns that include the maximum number of fail cells, which are the first row, the fourth row, the first column, and the third column. Here, the maximum value for the number of fail cells is 1.

Next, the determining section 150 determines that there are 4 rows or columns having the maximum number of fail cells and the minimum corresponding weighting stored in the row-weighting storage section 136 and the column-weighting storage section 138. When there are two or more rows or columns that have the minimum weighting, the determining section 150 compares the total number of columns already set as repair targets to the number of rows already set as repair targets. Since the total number of columns already set as repair targets, which is 2, is greater than the total number of columns already set as repair targets, which is 0, the determining section 150 prioritizes the first row and the fourth row having the minimum weighting as repair targets.

FIG. 4C shows an example in which the analyzing section 130 of the present embodiment has set two repair target rows. The determining section 150 clears the fail cell information in the first row and the fourth row set as repair targets in the buffer section 122. Specifically, the determining section 150 clears the fail cells at the first row and first column and the fifth row and third column. As a result, all of the fail cells are cleared, and the analyzing section 130 ends the repair analysis for this memory region.

As described above, in the present embodiment, the determining section 150 can repair the memory region stored in the buffer section 122 by setting two rows and two columns, specifically the first row, the fourth row, the second column, and the fifth column, as repair targets. In this way, the determining section 150 can efficiently repair the fail cells by performing a repair analysis based on the values stored in the row-oriented fail number storage section 132, the column-oriented fail number storage section 134, the row-weighting storage section 136, and the column-weighting storage section 138.

The present embodiment describes an example in which the determining section 150 clears the fail cell information in the buffer section 122 for rows and columns set as repair targets. Instead, without clearing the information in the buffer section 122, the determining section 150 may clear the fail cell information in the row-oriented fail number storage section 132, the column-oriented fail number storage section 134, the row-weighting storage section 136, and the column-weighting storage section 138.

For example, the determining section 150 may subtract the number of fail cells included in each row or column set as a repair target from the corresponding row-oriented fail number storage section 132 or column-oriented fail number storage section 134. In this way, the determining section 150 can clear the row-oriented fail number storage section 132 and the column-oriented fail number storage section 134.

Similarly, the determining section 150 may subtract the number of fail cells stored in the row-oriented fail number storage section 132 or the column-oriented fail number storage section 134 prior to the clearing corresponding to the fail cells included in the rows or columns set as repair targets from the row-weighting storage section 136 or the column-weighting storage section 138. In this way, the determining section 150 can clear the row-weighting storage section 136 and the column-weighting storage section 138.

In the manner described above, the determining section 150 can perform the repair analysis without clearing the information in the buffer section 122. In this case, the analyzing section 130 uses the buffer section 122 to reference the fail cell position information, and therefore the buffer section 122 may be omitted. In other words, the analyzing section 130 may directly access the fail memory section 120 to reference the fail cell position information, to update the fail cell information in the row-oriented fail number storage section 132, the column-oriented fail number storage section 134, the row-weighting storage section 136, and the column-weighting storage section 138.

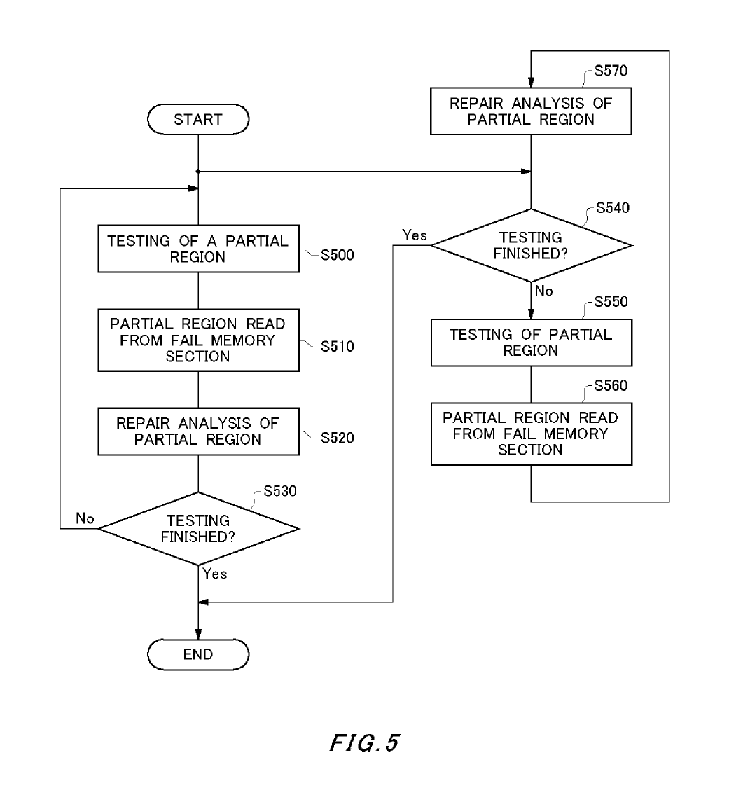

FIG. 5 shows an exemplary modification of the operational flow of the test apparatus 100 according to the present embodiment. In the present modification, the testing section 110 sequentially performs testing of each memory region in the memory under test 10 and sequentially switches among a plurality of fail memory sections 120 to store the fail cell information indicating the test results for each memory region, and the analyzing section 130 performs a repair analysis of each memory region based on the fail cell information for the memory region stored in the corresponding fail memory section 120. In other words, the test apparatus 100 performs the testing by the testing section 110 and the repair analysis by the analyzing section 130 temporally in parallel.

For example, the testing section 110 may test the even-numbered memory regions of the memory under test 10 and store the fail cell information indicating the test results in a second fail memory section, and the analyzing section 130 may perform the repair analysis in parallel for odd-numbered memory regions based on the test result information for the odd-numbered memory regions stored in a first fail memory section. Furthermore, the testing section 110 may test the odd-numbered memory regions of the memory under test 10 and store the fail cell information indicating the test results in the first fail memory section, and the analyzing section 130 may perform the repair analysis in parallel for the even-numbered memory regions based on the test result information for the even-numbered memory regions stored in the second fail memory section.

The testing section 110 tests a partial memory region of the memory under test 10 (S500). For example, the testing section 110 may test a first region of the memory under test 10. The testing section 110 includes a plurality of fail memory sections 120, and stores the fail information indicating the test results for the first memory region in a first fail memory section among the plurality of fail memory sections 120. Next, the buffer section 122 reads the fail information for the first region stored in the first fail memory, and stores this fail information (S510).

The analyzing section 130 repeats the process of step S320 to step S380 shown in FIG. 3, to perform the repair analysis for the first region (S520). The testing section 110 repeats the process of step S500 to step S520 to perform testing and a repair analysis on the next odd-numbered memory region in the memory under test 10, until testing is finished (S530).

On the other hand, while the analyzing section 130 is performing the repair analysis at step S510 and step S520, the testing section 110 determines whether there is a region other than the first region to be tested among the memory regions of the memory under test 10, based on a test program or the like (S540). When there is another region, e.g. a second region, to be tested, the testing section 110 tests the second region in parallel with the repair analysis performed by the analyzing section 130 (S550).

The testing section 110 stores the fail information for the second region in a second fail memory section among the plurality of fail memory sections 120. Next, the buffer section 122 reads the fail information of the second region stored in the second fail memory section, and stores this fail information (S560). Furthermore, in parallel with the testing of a third region by the testing section 110, the analyzing section 130 performs the repair analysis of the second region (S570). The testing section 110 repeats the process from step S550 to step S540 to perform testing and a repair analysis on the next even-numbered region in the memory under test 10, until testing is finished (S540).

By performing the testing by the testing section 110 and the repair analysis by the analyzing section 130 in parallel in this manner, the test apparatus 100 can shorten the time required for the testing and repair analysis of the memory under test 10. Furthermore, by storing the test results for odd-numbered regions in the first fail memory section and storing the test results for even-numbered regions in the second fail memory section, the capacity of the fail memory section in the test apparatus 100 can be decreased.

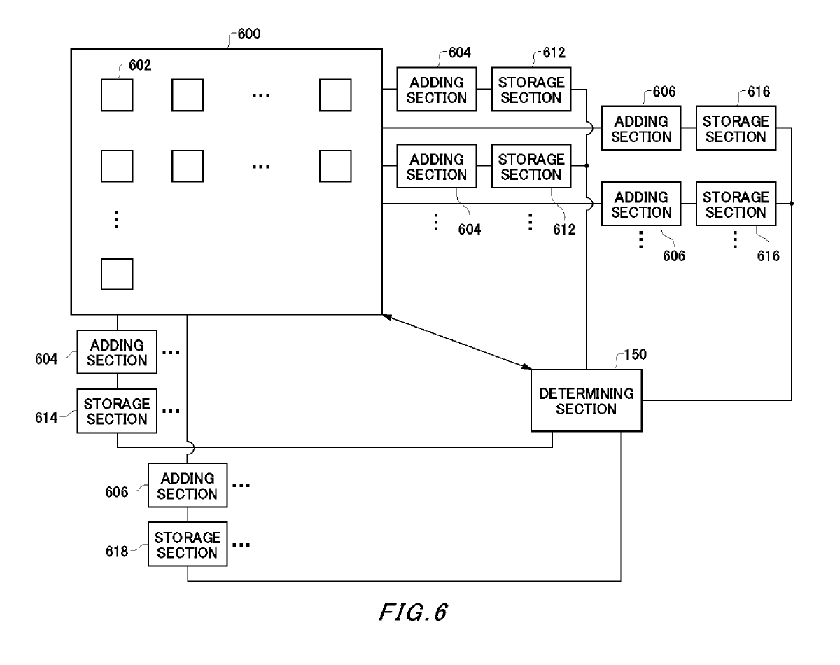

FIG. 6 shows a modification of the analyzing section 130 according to the present embodiment. The present modification shows an example in which the analyzing section 130 is realized by hardware. The analyzing section 130 includes a register matrix circuit 600, first adding sections 604, second adding sections 606, first storage sections 612, second storage sections 614, third storage sections 616, and fourth storage sections 618.

The register matrix circuit 600 reads the fail cell information of a partial memory region from the fail memory section 120, and stores this information. The register matrix circuit 600 includes a plurality of register sections 602. The number of register sections 602 in the register matrix circuit 600 may be greater than or equal to the number of addresses designating rows and columns of the memory region read from the fail memory section 120.

The register sections 602 in the register matrix circuit 600 may correspond one-to-one to the addresses designated by the rows and columns of the memory region. In other words, one register section 602 may record information for one memory cell of the memory region. The register sections 602 may be flip-flop circuits.

Each first adding section 604 may calculate the sum of the number of fail cells stored in the register sections 602 corresponding respectively to each row and each column of the memory region. Each second adding section 606 selectively adds together the numbers stored in the first storage section 612 or the second storage section 614 connected thereto.

A first storage section 612 is provided for each row of register sections 602 in the memory region, and each first storage section 612 stores the number of fail cells summed for the row by the corresponding first adding section 604. A second storage section 614 is provided for each column of register sections 602 in the memory region, and each second storage section 614 stores the number of fail cells summed for the column by the corresponding first adding section 604.

A third storage section 616 is provided for each row of register sections 602 in the memory region, and each third storage section 616 stores the result of the summation by the corresponding second adding section 606 of the number of fail cells in columns containing a fail cell included in the corresponding row. For example, the second adding section 606 corresponding to the first row of the memory calculates the sum of the number of fail cells in the columns containing fail cells included in the first row. A fourth storage section 618 is provided for each column of register sections 602 in the memory region, and each fourth storage section 618 stores the result of the summation by the corresponding second adding section 606 of the number of fail cells in rows containing a fail cell included in the corresponding column. For example, the second adding section 606 corresponding to the first column of the memory calculates the sum of the number of fail cells in the rows containing fail cells included in the first column.

In this way, the analyzing section 130 of the present modification can replace the buffer section 122, the row-oriented fail number storage section 132, the column-oriented fail number storage section 134, the row-weighting storage section 136, and the column-weighting storage section 138 described in FIG. 1 with the respectively corresponding hardware of the register matrix circuit 600, the first storage section 612, the second storage section 614, the third storage section 616, and the fourth storage section 618. Therefore, the analyzing section 130 can perform the memory repair analysis using hardware.

Furthermore, the analyzing section 130 may further include a program logic device that can be configured by programming circuits therein, and is configured by programming the register matrix circuit 600 and the determining section 150. For example, the analyzing section 130 may be formed by a gate array in which overwriting can be performed, such as an FPGA. Therefore, the analyzing section 130 can be realized with hardware having high speed and simple design.

The above embodiments describe a test apparatus 100 that includes the testing section 110, the fail memory section 120, the analyzing section 130, and the repairing section 140, and performs testing, a repair analysis, and a repair process on a memory under test. Instead, the analyzing section 130 may be a memory repair analysis apparatus. The test apparatus 100 need not include the testing section 110 and the fail memory section 120, and the repairing section 140 may be a repair apparatus. Here, the memory repair analysis apparatus may further include a fail memory section that reads and stores all of the test result information stored in the fail memory section 120 of the test apparatus 100.

Instead, the analyzing section 130 and the repairing section 140 may be a memory repair analysis apparatus. In this case, the memory repair analysis apparatus further includes the fail memory section.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A memory repair analysis apparatus that performs a repair analysis on a memory under test including spare row regions for repairing memory regions in a row direction and spare column regions for repairing memory regions in a column direction, the memory repair analysis apparatus comprising:
a row-oriented fail number storage section that stores the number of fail cells in each row;
a column-oriented fail number storage section that stores the number of fail cells in each column;
a row-weighting storage section that, for each row, stores the total number of fail cells in each column containing a fail cell included in the row;
a column-weighting storage section that, for each column, stores the total number of fail cells in each row containing a fail cell included in the column; and
a determining section that determines which of the spare row regions and the spare column regions are to replace the fail cells, based on the values stored in the row-oriented fail number storage section, the column-oriented fail number storage section, the row-weighting storage section, and the column-weighting storage section.

2. The memory repair analysis apparatus according to claim 1, wherein
the determining section determines which of the spare row regions and the spare column regions are to be used for replacement while prioritizing rows or columns for which a larger number of fail cells is stored in the row-oriented fail number storage section or the column-oriented fail number storage section.

3. The memory repair analysis apparatus according to claim 2, wherein
among a plurality of rows or columns for which the same number of fail cells is stored in the row-oriented fail number storage section and the column-oriented fail number storage section, the determining section determines which of the spare row regions and the spare column regions are to be used for replacement while prioritizing rows or columns for which a smaller total number is stored in the row-weighting storage section or the column-weighting storage section.

4. The memory repair analysis apparatus according to claim 3, wherein
when a plurality of rows or columns have the same number of fail cells stored in the row-oriented fail number storage section and the column-oriented fail number storage section and the same total values stored in the row-weighting storage section and the column-weighting storage section, the determining section compares the total number of rows that have already been set to be replaced by row repair regions and the total number of columns that have already been set to be replaced by column repair regions, and when the total number of columns is greater, determines that the plurality of rows are to be given priority for replacement with spare row regions.

5. The memory repair analysis apparatus according to claim 3, wherein
when a plurality of rows or columns have the same number of fail cells stored in the row-oriented fail number storage section and the column-oriented fail number storage section and the same total values stored in the row-weighting storage section and the column-weighting storage section, if the number of fail numbers greater than or equal to 1 stored in the column-oriented fail number storage section is greater than the number of fail numbers greater than or equal to 1 stored in the row-oriented fail number storage section, the determining section determines that the rows are to be replaced while prioritizing the spare column regions.

6. The memory repair analysis apparatus according to claim 1, wherein
the determining section clears fail cell information for rows and columns that have been determined to be replaced by the spare row regions or the spare column regions, and updates the values stored in the row-oriented fail number storage section, the column-oriented fail number storage section, the row-weighting storage section, and the column-weighting storage section.

7. The memory repair analysis apparatus according to claim 1, further comprising:
a fail memory section that stores fail cell information for each of a plurality of memory regions of the memory under test; and
a register matrix circuit that reads the fail cell information of a partial memory region from the fail memory section and stores the read fail cell information.

8. The memory repair analysis apparatus according to claim 7, further comprising a program logic device that is configurable by programming circuits therein, and is configured by programming the register matrix circuit and the determining section.

9. A test apparatus comprising:
a testing section that tests a memory under test by exchanging electrical signals with the memory under test; and
the memory repair analysis apparatus according to claim 1.

10. The test apparatus according to claim 9, wherein
the testing section sequentially tests each memory region of the memory under test, and sequentially switches between a plurality of fail memory sections to store fail cell information indicating test results for each memory region, and
the memory repair analysis apparatus performs a repair analysis for each memory region based on the fail cell information stored in the fail memory sections for the memory region.

11. The test apparatus according to claim 10, wherein
the testing section tests even-numbered memory regions of the memory under test and stores the fail information indicating the test results of the even-numbered memory regions in a second fail memory section, and
in parallel with the testing of the even-numbered memory regions, the memory repair analysis apparatus performs the repair analysis of odd-numbered memory regions based on test result information for the odd-numbered memory regions stored in a first fail memory section.

12. The test apparatus according to claim 11, wherein
the testing section tests the odd-numbered memory regions of the memory under test and stores the test results of the odd-numbered memory regions in the first fail memory section, and
in parallel with the testing of the odd-numbered memory regions, the memory repair analysis apparatus performs the repair analysis of the even-numbered memory regions based on test result information for the even-numbered memory regions stored in the second fail memory section.

13. The test apparatus according to claim 9, further comprising a repairing section that performs repair by replacing the columns or rows determined by the memory repair analysis apparatus to be replaced by the spare row regions or the spare column regions, in the order in which the determination was made by the memory repair analysis apparatus.

14. A method for performing a memory repair analysis on a memory under test including spare row regions for repairing memory regions in a row direction and spare column regions for repairing memory regions in a column direction, the method comprising:
row-oriented fail cell calculation of calculating the number of fail cells in each row;
column-oriented fail cell calculation of calculating the number of fail cells in each column;
row-weighting calculation of, for each row, calculating the total number of fail cells in each column containing a fail cell included in the row;
column-weighting calculation of, for each column, calculating the total number of fail cells in each row containing a fail cell included in the column;
determining which of the spare row regions and the spare column regions are to be used for replacement while prioritizing columns or rows that have a greater number of row-oriented fail cells or column-oriented fail cells; and
when the rows or columns having a greater number of row-oriented fail cells or column-oriented fail cells have the same number of fail cells, determining which of the spare row regions and the spare column regions are to be used for replacement while prioritizing columns or rows that have a lower total for the row-weighting or the column-weighting.
